(19) United States
(12) Patent Application Publication
(10) Pub. No.: US 2009/0197421 A1
(43) Pub. Date: Aug. 6, 2009

(54) CHEMISTRY AND COMPOSITIONS FOR MANUFACTURING INTEGRATED CIRCUITS

(75) Inventor: Dave Keller, Boise, ID (US)

Correspondence Address: MUETING, RAASCH & GEBHARDT, P.A., P.O. BOX 581336, MINNEAPOLIS, MN, 55458-1336, US

(73) Assignee: MICRON TECHNOLOGY, INC., Boise, ID (US)

(21) Appl. No.: 12/023,163

(22) Filed: Jan. 31, 2008

(51) Int. Cl. H01L 21/3065

(52) U.S. Cl. 438/714; 257/43; 257/E27.01

(57) ABSTRACT

Methods of removing metal-containing materials during the manufacture of integrated circuits are disclosed. Generally, the methods include providing a substrate assembly that includes a metal-containing material, contacting the metal-containing material with a reactive composition that includes a chlorocarbon material under conditions effective to form a reaction product, and removing the reaction product.

### BACKGROUND

During certain steps in the manufacture of integrated circuits, it may be desirable to remove a portion of a high-K dielectric material (e.g., Al₂O₃ or HfO₂) incorporated into a substrate assembly. Often, photolithographic techniques are used. That is, a surface may be partially masked with the exposed portion of the surface being the area to be removed. Exposed areas of the surface are contacted with a reactive composition in order, for example, to remove a portion of a layer or to form a recess, such as, for example, a contact hole or a via hole in the material.

Dry etching is one example of a process by which surface material can be removed during the manufacture of integrated circuits. Dry etching, sometimes also referred to as plasma etching, can provide, for example, the ability to generate isotropic or anisotropic etch profiles, faithful transfer of lithographically defined photoresist patterns into underlying layers, high resolution, limited handling of dangerous acids and solvents, cleanliness, process control, and/or ease of automation.

Certain dry etching compositions include boron-containing materials such as, for example, BCl₃. When BCl₃ is used to etch certain high-κ materials, boron can become implanted in underlying semiconductor materials (e.g., polysilicon), thereby modifying the electrical characteristics of the semiconductor material. This can be undesirable when, for example, the polysilicon material is designed to be a component of an integrated circuit such as, for example, a transistor.

### BRIEF DESCRIPTION OF THE DRAWING

FIG. 1 shows a cross-sectional view of a substrate assembly prior to removing metal-containing material using a reactive composition that includes a chlorocarbon material.

FIG. 2 shows the substrate assembly of FIG. 1 after removing metal-containing material using a reactive composition that includes a chlorocarbon material.

FIG. 3 shows an x-direction cross-sectional scanning electron microscope (SEM) view of a substrate assembly prepared by removing metal-containing material using a reactive composition that includes a chlorocarbon material and O₂.

FIG. 4 shows a y-direction cross-sectional SEM view of the substrate assembly of FIG. 3.

### DETAILED DESCRIPTION OF ILLUSTRATIVE EMBODIMENTS

This disclosure relates, generally, to methods involved in the manufacture of integrated circuits (e.g., memory devices, processors, etc.) such as those used, for example, in consumer products and systems (e.g., cameras, phones, wireless devices, displays, chip sets, set top boxes, games, vehicles, etc.). Integrated circuits typically are formed on silicon substrates or wafers, which can include active semiconductor devices with structured processes for a wide range of stacked materials.

Generally, the method includes providing a substrate assembly that includes a metal-containing material on at least a portion of the substrate assembly surface, providing contact between the metal-containing material and a reactive composition that includes a chlorocarbon material under conditions effective to form a reaction product; and removing the reaction product. In some embodiments, the method provides selective removal of the metal-containing material relative to other materials of the substrate assembly (e.g., polysilicon, SiO₂, a mask layer, etc.). In some embodiments, the method may be performed at a temperature of no greater than 70° C. such as, for example, a temperature between 30° C. and 60° C. In still other embodiments, the reactive composition can further include O₂.

“Chlorocarbon material” refers to any organic material having at least one chlorine atom bonded to a carbon atom, or combinations of such materials.

Chlorocarbon materials include, for example, CCl₄ (carbon tetrachloride), CHCl₃ (chloroform, trichloromethane), CH₂Cl₂ (dichloromethane), CH₃Cl (methyl chloride), COCl₂ (phosgene), or any combination thereof.

“Substrate assembly” as used herein refers to a semiconductor substrate having one or more layers, structures, or regions formed thereon. A base semiconductor layer is typically the lowest layer of silicon material on a wafer or a silicon layer deposited on another material, such as, for example, silicon on sapphire. When reference is made to a substrate assembly, various process steps may have been previously used to form or define one or more integrated circuit components. As used herein, the term “integrated circuit component” refers generally to a region, junction, structure, feature, and/or opening such as, for example, a contact (including a first level contact), an electrode, a source, a drain, a transistor, an active area, an implanted region, a via, an interconnect including a local interconnect or an interconnect formed between interlevel dielectric layers, a contact opening, a high aspect ratio opening, a capacitor plate, a barrier for a capacitor, etc.

“Layer,” as used herein, is meant to include layers specific to the semiconductor industry, such as, but clearly not limited to, a barrier layer, dielectric layer (i.e., a layer having a high dielectric constant), and conductive layer. The term “layer” is synonymous with the term “film” frequently used in the semiconductor industry. The term “layer” is also meant to include layers found in technology outside of semiconductor technology, such as coatings on glass. For example, such layers can be formed directly on fibers, wires, etc., which are substrates other than semiconductor substrates. Further, the layers can be formed adjacent to (e.g., directly on) the lowest semiconductor surface of the substrate, or they can be formed adjacent to any of a variety of layers (e.g., surfaces) as in, for example, a patterned wafer. As used herein, layers need not be continuous, and in certain embodiments are discontinuous. Unless otherwise stated, as used herein, a layer or material “adjacent to” or “on” a surface (or another layer) is intended to be broadly interpreted to include not only constructions having a layer or material directly on the surface, but also constructions in which the surface and the layer or material are separated by one or more additional materials (e.g., layers).

“Reactive composition” refers to a composition that, under appropriate conditions, can react with a target material of a substrate assembly surface. The term may apply to a composition prior to the application of one or more conditions (e.g., energy) that may be required to initiate reaction between the composition or a component of the composition and the target material.

Integrated circuits continue to advance towards smaller devices with more memory. In the manufacture of semiconductor integrated circuits, dielectric materials such as, for example, silicon dioxide (SiO₂), silicon nitride (SI₃N₄) or silicon oxynitride (SiON) have been used. As technology has progressed, integrated circuit device geometry has become smaller and the demand for manufacturing progressively thinner integrated circuit devices has increased. When integrated circuit devices approach thicknesses of a few nanometers or less, conventional dielectric materials can undergo electronic breakdown and may no longer provide the memory storage needed.

To address this problem, high dielectric constant materials (high-κ dielectric materials) have been used to manufacture semiconductor chips. Examples of high-κ materials include metal-containing materials such as, for example, aluminum oxide, (Al₂O₃), hafnium oxide (HfO₂), zirconium oxide (ZrO₂) and mixtures thereof, and metal silicates such as HfSiₓO_{y}, ZrSiO₄, and mixtures thereof. High-κ materials, however, can be difficult to remove using dry etch methods. High-κ materials typically are very stable and resistive against etching reactions.

Conventional methods of etching high-κ dielectric materials, typically involve chlorine (Cl₂) gas at a high wafer temperature, and/or fluorine gas (F₂).

These methods posses certain disadvantages. For example, Cl₂-based chemistry aggressively etches polysilicon, resulting in low selectivity of removing metal-containing materials relative to polysilicon. Also, etched high-κ dielectric materials can form a residue on the wafer after etching, yielding low capacitive structures or defective wafers. Fluorine also presents certain challenges for etching high-κ dielectric materials. For example, fluorine can produce a metal fluoride product that is nonvolatile and thus difficult to remove from the reactor.

Also, fluorine-containing materials such as, for example, CF₄ or CH₂F₂ can fail to provide a desired level of selectivity. For example, while fluorine-containing materials can remove metal-containing high-κ materials, they also can remove, for example, shallow trench isolation oxide materials.

Methods described herein generally provide selective removal of metal-containing materials such as high-κ dielectric materials relative to semiconductor materials or mask materials that can be employed during the manufacture of integrated circuits on a substrate assembly.

A wide variety of materials may be used to form the substrate assembly such as, for example, silicon oxide, borophosphosilicate glass (BPSG), silicon such as, e.g., conductively doped polysilicon, monocrystalline silicon, etc. (for this disclosure, appropriate forms of silicon are simply referred to as “silicon”, for example in the form of a silicon wafer), tetraethylorthosilicate (TEOS) oxide, spin on glass (i.e., a thin layer of SiO₂, optionally doped, deposited by a spin on process), TiN, TaN, W, Ru, Al, Cu, noble metals, etc. A substrate assembly also may contain a layer that includes platinum, iridium, iridium oxide, rhodium, ruthenium, ruthenium oxide, strontium ruthenate, lanthanum nickelate, titanium nitride, tantalum nitride, tantalum-silicon-nitride, silicon dioxide, aluminum, gallium arsenide, glass, etc., and other existing or to-be-developed materials used in constructions, such as, for example, dynamic random access memory (DRAM) devices, static random access memory (SRAM) devices, ferroelectric memory (FERAM) devices, NAND flash devices, NOR flash devices, microprocessors, microcontrollers, and application specific integrated circuit (ASIC) chips, for example. The layers of a substrate assembly can be formed directly on a surface of the base semiconductor layer, or they can be formed on any of a variety of the layers (i.e., surfaces) as in a patterned wafer, for example.

The metal-containing material can contain any metal or metal alloy suitable for forming an integrated circuit component. As used herein, a metal-containing material refers to a material that may consist entirely of one or more metals, or may also include one or more other elements in addition to the one or more metals. In some embodiments, for example, the metal-containing material can include a metal oxide such as, for example, Al₂O₃, HfO₂, ZrO₂, HfSiₓO_{y}, ZrSiO₄, or combinations thereof. Such combinations can include, for example, a plurality of metal-containing layers or films in which two or more of the layers or films include different metal-containing materials (e.g., a sandwich of, for example, Al₂O₃ and HfO₂). In some embodiments, the metal-containing material can be a high-κ dielectric material.

The metal-containing material may be formed on a surface of the substrate assembly by any suitable technique including but not limited to atomic layer deposition (ALD), chemical vapor deposition (CVD), electroplating, electroless plating, evaporation, and sputtering.

ALD and CVD are two vapor deposition processes often employed to form thin, continuous, uniform layers onto substrates such as, for example, semiconductor substrates or dielectric layers in a semiconductor device. ALD permits deposition of a single atomic layer of the material being formed.

Deposition of metal by ALD can minimize the time temperature exposure necessary to form the metal-containing material.

Generally, using either vapor deposition process, a precursor composition including one or more metals of the metal-containing material is vaporized in a deposition chamber and optionally combined with one or more reaction gases and directed to and/or contacted with the substrate to form a metal layer on the substrate. It will be readily apparent to one skilled in the art that the vapor deposition process may be enhanced by employing various related techniques such as plasma assistance, photo assistance, laser assistance, as well as other techniques.

Generally, ALD involves a series of deposition cycles conducted in a process chamber (i.e., a deposition chamber). Typically, during each cycle, metal atoms are chemisorbed to a deposition surface (e.g., a substrate assembly surface or a previously deposited underlying surface such as material from a previous ALD cycle), forming, for example, a monolayer of atoms. Thereafter, if desired, one or more subsequent layers of metal atoms may be deposited by repeating the deposition process until the composition of the metal-containing layer is attained.

ALD, as used herein, is also meant to include processes designated by related terms such as, “chemical vapor atomic layer deposition,” “atomic layer epitaxy” (ALE) (see U.S. Pat. No. 5,256,244 to Ackerman), molecular beam epitaxy (MBE), gas source MBE, or organometallic MBE, and chemical beam epitaxy when performed with alternating pulses of precursor composition(s), reactive gas, and purge (e.g., inert carrier) gas.

A typical CVD process may be carried out in a chemical vapor deposition reactor, such as a deposition chamber available under the trade designation of 7000 from Genus, Inc. (Sunnyvale, Calif.), a deposition chamber available under the trade designation of 5000 from Applied Materials, Inc. (Santa Clara, Calif.), or a deposition chamber available under the trade designation of Prism from Novelus, Inc. (San Jose, Calif.). However, any deposition chamber suitable for performing CVD may be used.

Once a metal-containing material is formed, an integrated circuit component may be formed from the metal-containing material by removing at least a portion of the metal-containing material. A portion of the metal-containing material may be removed by one or more of a variety of processes. One such process is dry etching.

Dry etching is also sometimes referred to as plasma etching. Generally, it may include generating a reactive etchant species in a plasma; diffusing the reactive etchant species to the surface of the material being etched; adsorbing the reactive etchant species on the surface; chemical reaction between the reactive etchant species and the material being etched, forming volatile byproducts; desorbing the byproducts from the surface such as, for example, with the aid of ion bombardment; and diffusing the desorbed byproducts into the bulk of the gas.

Dry etching is typically performed using an apparatus that includes a chamber (e.g., a plasma chamber), a vacuum system, a power supply, and a gas delivery system in fluid communication with the chamber. In some embodiments, the apparatus can further include an end point detector. Wafers to be etched may be loaded into the chamber of the apparatus. The vacuum system is used to reduce the pressure inside the chamber. After a vacuum is established, the chamber is filled with a gaseous reactive composition. A power supply creates a radio frequency field through electrodes in the chamber. The field energizes the gaseous reactive composition to a plasma state. In the energized state, a reactive etchant species of the composition contacts a portion of the surface to be etched, converting the surface material into volatile components that are removed from the system by the vacuum system. In a typical system, the rate at which the reactive composition removes material that is to be etched can vary from about 600 Å/min. to about 2000 Å/min.

The selectivity of a reactive composition can be important to the dry etching process. Selectivity generally refers to the ability of a reactive composition to preferentially remove the target material intended for removal relative to nontarget materials (e.g., photoresist, semiconductor, etc.). Selectivity can be determined by the ratio of the etch rate of the target material being removed to the etch rate of nontarget materials. In particular, a reactive composition should have limited reactivity with a mask material that may cover a portion of the surface, thereby protecting that portion of the surface from the etching process. A reactive composition also should have limited reactivity with material beneath the material being etched.

In general, a reactive composition can include one or more of the following characteristics: high selectivity against etching the masking material over the material being etched; high selectivity against removing the material under the layer being removed; high etch rate for the material being removed; and etching uniformity. A reactive composition also can be selected to provide a safe, clean, and automation-ready etching process.

As used herein, a reactive composition exhibits selectivity if its ratio of etch rates of the metal-containing material and underlying nontarget material or overlying masking material is at least 1.5:1. In some embodiments, the ratio of etch rates of the metal-containing material and nontarget material is at least 2:1. In other embodiments, the ratio of etch rates of the metal-containing material and nontarget material is at least 2.5:1. In still other embodiments, the ratio of etch rates of the metal-containing material and nontarget material is at least 3:1.

In the methods described herein, the reactive composition includes a chlorocarbon material. In some embodiments, the chlorocarbon material may include, for example, a C₁-C₆ compound having at least one chlorine atom bonded to a carbon atom, although the methods described herein may be practiced using chlorocarbon materials having a greater number of carbon atoms. In some embodiments, the chlorocarbon material may include a C₁ chlorocarbon compound, while in alternative embodiments, the chlorocarbon material can include a C₂, C₃, C₄, C₅, or C₆ compound. Suitable chlorocarbon materials include, for example, CCl₄, CHCl₃, CH₂Cl₂, CH₃Cl, COCl₂, or any combination thereof. These chlorocarbon materials can provide selective removal of metal-containing materials such as, for example, high-κ dielectric materials (e.g., Al₂O₃, HfO₂, ZrO₂, HfSiₓO_{y}, ZrSiO₄, etc.) relative to other materials (e.g., SiO₂, polysilicon, masking materials, shallow trench isolation oxide, etc.) in a substrate assembly. In some embodiments, the reactive composition can include a combination of two or more chlorocarbon materials.

Moreover, chlorocarbon materials do not deposit atoms into polysilicon that substantially alter the electrical characteristics of the polysilicon. Carbon atoms from the chlorocarbon materials may be deposited into polysilicon during removal of metal-containing material. However, because carbon and silicon are elements that have similar electron configurations in their valence shell, they are chemically similar. Thus, deposition of carbon atoms into polysilicon does not substantially alter the electrical characteristics of the polysilicon. Consequently, chlorocarbon materials may be particularly well-suited for removal of metal-containing materials during the manufacture of a substrate assembly in which polysilicon underlying a metal-containing material is designed to form a transistor. In contrast, certain boron-containing materials that are often used during the manufacture of integrated circuits can chemically remove metal-containing materials, but such boron-containing materials can alter the electrical characteristics of polysilicon.

In some embodiments, the reactive composition can further include one or more additional components. For example, in some embodiments, the reactive composition can further include a halogen such as, for example, Cl₂. Thus, suitable reactive compositions can include mixtures of, for example, CCl₄/Cl₂, CHCl₃/Cl₂, CH₂Cl₂/Cl₂, CH₃Cl/Cl₂, and COCl₂/Cl₂. In some embodiments, the reactive composition may further include a carrier gas such as, for example, a Noble gas. Suitable carrier gases include, for example, Ar. In some embodiments, the reactive composition can include a combination of two or more additional components.

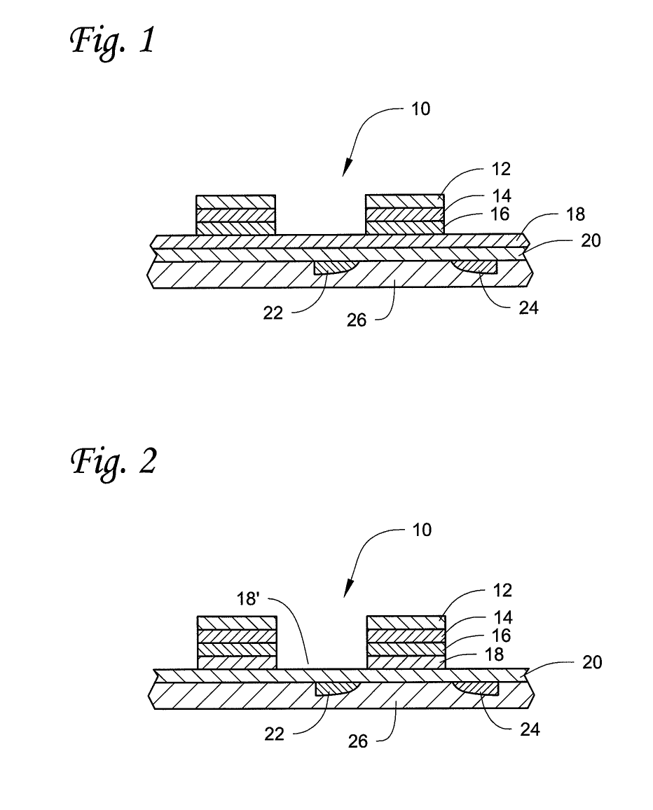

FIG. 1 shows a side cross-sectional view of a substrate assembly (10) that includes an active device that includes a control gate and a floating gate. The generalized substrate assembly shown in FIG. 1 includes a cap oxide (12), metal stack (e.g., WSiₓ, W,Wn, Ti, etc.) (14), control gate polysilicon (16), high-κ intrapoly dielectric material (e.g., Al₂O₃) (18), floating gate polysilicon (20), a source (22), a drain (24), and a substrate (26). FIG. 1 shows the substrate assembly prior to removal of a portion of the high-κ intrapoly dielectric material (18). FIG. 2 shows a side cross-sectional view of the substrate assembly (10) after removal of a portion of the high-κ intrapoly dielectric material (18′) using any one of the reactive compositions described herein that includes a chlorocarbon material.

In one embodiment, a substrate assembly according to FIG. 1 can include a stack that includes cap SiO₂ (12), WSiₓ (14), polysilicon (16), Al₂O₃ (18), and floating gate polysilicon (20). The substrate assembly (10) may be etched using, for example, a 2300 VERSYS KIYO (Lam Research Corp., Fremont, Calif.) plasma etch chamber at, for example, 5 milliTorr (mTorr), 1200 Watts, and a 50 Volt bias. The substrate assembly (10) may be etched using, for example, 60 sccm of CHCl₃/20 sccm Cl₂ in 240 sccm Ar for 30 seconds, and 60 sccm of CHCl₃ in 240 sccm Ar for 40 seconds. The selective removal of Al₂O₃ is shown (18′) in FIG. 2.

In some embodiments, the reactive composition can further include O₂. A reactive composition that includes O₂ can increase selectivity of the removal of the metal-containing material relative to, for example, polysilicon. For example, a reactive composition that includes CH₂Cl₂ and O₂ can increase the selectivity of removal of the metal-containing material relative to polysilicon (and/or SiO₂) compared to a reactive composition that includes CH₂Cl₂ but does not include O₂. In contrast, it can be undesirable to add O₂ to certain conventional reactive compositions such as, for example, those that include boron because the boron can react with the O₂ to form nonvolatile B₂O₃ particles that can contaminate the manufacturing process.

The reactive composition may be formed, for example, by controlling the flow rate of components of the composition into the chamber. Each component of the reactive composition may have different flow rates. In some cases, however, components may have the same flow rate.

For example, a reactive composition can be formed by providing a chlorocarbon material at a flow rate of from at least 20 to no more than 500 standard cubic centimeters per minute (sccm). For example, a chlorocarbon material such as, for example, CHCl₃ may be provided at a flow rate of at least 20 sccm, at least 40 sccm, at least 60 sccm, or at least 70 sccm. The chlorocarbon material (e.g., CHCl₃) may be provided at a flow rate of no more than 500 sccm, no more than 200 sccm, no more than 100 sccm, no more than 80 sccm, or no more than 50 sccm. In some embodiments, CHCl₃ can be provided at a flow rate of from 40 sccm to 80 sccm. In one particular embodiment, CHCl₃ can be provided at a flow rate of 60 sccm.

In certain embodiments, a reactive composition can include a combination of a chlorocarbon material and a halogen. A reactive composition may be formed by providing, for example, CHCl₃ as described in the immediately preceding paragraph, and additionally providing a halogen such as, for example, Cl₂ at a flow rate of from at least 5 to no more than 500 sccm. For example, the halogen (e.g., Cl₂) may be provided at a flow rate of at least 5 sccm, at least 10 sccm, at least 20 sccm, or at least 50 sccm. The halogen may be provided at a flow rate of no more than 500 sccm, no more than 200 sccm, no more than 100 sccm, no more than 80 sccm, or no more than 50 sccm. In some embodiments, Cl₂ can be provided at a flow rate of from 10 sccm to 50 sccm. In one particular embodiment, Cl₂ can be provided at a flow rate of 20 sccm.

In some embodiments, the method may be performed by cycling two or more reactive compositions. In one embodiment, the method includes contacting the substrate assembly with a first reactive composition that includes CHCl₃ provided at 60 sccm and Cl₂ provided at 20 sccm for, for example, 30 seconds, and then contacting the substrate assembly with a second reactive composition that includes CHCl₃ provided at 60 sccm for, for example, 40 seconds.

In certain embodiments, the reactive composition can further include, for example, O₂ provided at a flow rate of from at least 1 sccm to no more than 200 sccm. For example, O₂ can be provided at a flow rate of at least 1 sccm, at least 5 sccm, at least 20 sccm, at least 30 sccm, or at least 50 sccm. O₂ may be provided at a flow rate of no more than 200 sccm, no more than 60 sccm, no more than 50 sccm, no more than 30 sccm, or no more than 20 sccm. In some embodiments, O₂ may be provided at a flow rate of from about 5 sccm to about 20 sccm. In one particular embodiment, O₂ is provided at a flow rate of 10 sccm. In another particular embodiment, O₂ is provided at a flow rate of 20 sccm.

The use of a chlorocarbon material also permits removing metal-containing material at a temperature of no greater than 90° C. Thus, in some embodiments, the method may be performed at a temperature of no greater than 90° C., although the method may be performed at temperature higher than 90° C. In certain cases, it may be desirable to perform the method at a temperature of no greater than 90° C. in order to practice the method at a temperature that allows the integrity of a masking material to be maintained. Certain masking materials may begin to flow at temperatures higher than about 90° C., thereby decreasing their functional utility as masking materials. The use of a chlorocarbon material permits the selective removal of metal-containing materials (e.g., high-κ dielectric materials) at a temperature that maintains the utility of masking materials.

In certain embodiments, the method may be performed at a temperature of from about 30° C. to about 70° C., although the methods may be performed at temperatures outside of this range. In one embodiment, the method is performed at a temperature of about 60° C. to about 70° C.

### EXAMPLES

### Example 1

Flash wafers including a stack that includes cap SiO₂, WSiₓ, polysilicon, Al₂O₃, and a floating gate polysilicon were etched using a 2300 VERSYS KIYO (Lam Research Corp., Fremont, Calif.) plasma etch chamber at 5 milliTorr (mTorr), 1200 Watts, and a 50 Volt bias. The wafers were etched using 60 sccm of CHCl₃/20 sccm Cl₂ in 240 sccm Ar for 30 seconds, and 60 sccm of CHCl₃ in 240 sccm Ar for 40 seconds.

The Al₂O₃ was selectively removed relative to the cap SiO₂ and floating gate polysilicon.

### Example 2

Flash wafers as described in Example 1 were etched essentially as described in Example 1, except that the wafers were etched using 60 sccm of CHCl₃/30 sccm Cl₂/20 sccm O₂ in 240 sccm Ar for 40 seconds.

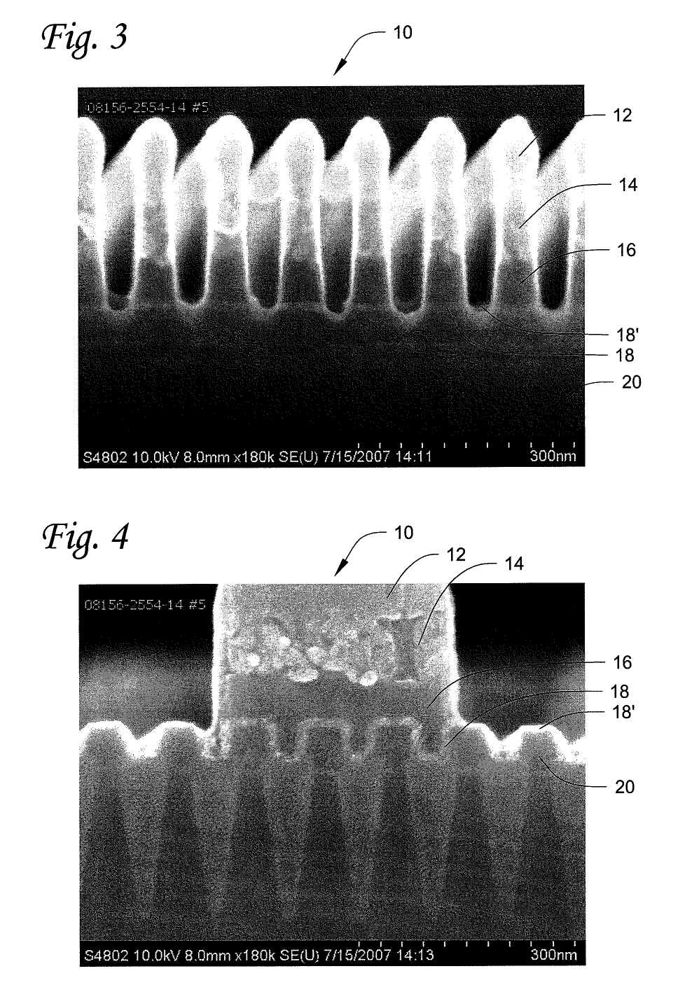

The Al₂O₃ was selectively removed relative to the cap SiO₂ and floating gate polysilicon. The results are shown in FIG. 3 (x-direction cross section view) and FIG. 4 (y-direction cross-section view).

The complete disclosures of the patents, patent documents, and publications cited herein are incorporated by reference in their entirety as if each were individually incorporated. Various modifications and alterations to the embodiments described herein will become apparent to those skilled in the art without departing from the scope of the present disclosure. It should be understood that this disclosure is not intended to be unduly limited by the illustrative embodiments set forth herein and that such embodiments are presented by way of example only with the scope of the disclosure intended to be limited only by the claims set forth herein as follows. As used herein, the term “comprising,” which is synonymous with “including” or “containing,” is inclusive, open-ended, and does not exclude additional unrecited elements or method steps.

What is claimed is:

1. A method for removing at least a portion of a metal-containing material, the method comprising:
providing a substrate assembly comprising a metal-containing material on at least a portion of the substrate assembly surface;
providing contact between the metal-containing material and a reactive composition comprising a chlorocarbon material under conditions effective to form a reaction product; and
removing the reaction product.

2. The method of claim 1 wherein the metal-containing material comprises a metal oxide.

3. The method of claim 2 wherein the metal oxide comprises at least one of: Al₂O₃, ZrO₂, or HfO₂.

4. The method of claim 1 wherein the chlorocarbon material comprises CCl₄, CHCl₃, CH₂Cl₂, CH₃Cl, COCl₂, or a combination thereof.

5. The method of claim 1 wherein the substrate assembly comprises a semiconductor material and the chlorocarbon material is selectively reactive with the metal-containing material compared to the semiconductor material.

6. The method of claim 5 wherein the semiconductor material comprises SiO₂.

7. The method of claim 5 wherein the semiconductor material comprises polysilicon.

8. The method of claim 1 wherein the conditions effective to form a reaction product comprise a temperature of no greater than 90° C.

9. The method of claim 1 wherein the conditions effective to form a reaction product comprise a temperature of from 30° C. to 70° C.

10. The method of claim 9 wherein the conditions effective to form a reaction product comprise a temperature of from 60° C. to 70° C.

11. The method of claim 9 wherein the conditions effective to form a reaction product comprise forming a plasma.

12. The method of claim 1 wherein the reactive composition further comprises O₂.

13. The method of claim 1 wherein the reactive composition further comprises Cl₂.

14. The method of claim 1 further comprising contacting the metal-containing material with a second reactive composition that comprises a second chlorocarbon material under conditions effective to form a second reaction product; and
removing the second reaction product.

15. A method for removing at least a portion of a metal-containing material, the method comprising:
providing a substrate assembly having a surface and a metal-containing material on at least a portion of the substrate assembly surface;
contacting at least a portion of the metal-containing material with a mask layer to define a masked portion of the metal-containing material and an exposed portion of the metal-containing material;
providing contact between at least a portion of the exposed portion of the metal-containing material and a reactive composition comprising a chlorocarbon material under conditions effective to form a reaction product; and
removing the reaction product.

16. The method of claim 15 wherein the reactive composition is selectively reactive with the exposed portion of the metal-containing material compared to the mask layer.

17. The method of claim 15 wherein the mask prevents contact between the reactive composition and at least a portion of the masked portion of the metal-containing material.

18. The method of claim 15 wherein the chlorocarbon material comprises CCl₄, CHCl₃, CH₂Cl₂, CH₃Cl, COCl₂, or a combination thereof.

19. The method of claim 15 wherein the metal-containing material comprises a high-κ dielectric.

20. The method of claim 15 wherein the reactive composition further comprises a halogen.

21. The method of claim 15 wherein the reactive composition further comprises a noble gas.

22. A method for removing at least a portion of a metal-containing material, the method comprising:
providing a substrate assembly having a surface and a metal-containing material on at least a portion of the substrate assembly surface;
placing the substrate assembly into an apparatus chamber;
providing a reactive composition to the apparatus chamber via a gas delivery system so that the reactive composition contacts the metal-containing material under conditions effective to form a reaction product, wherein the reactive composition comprises a chlorocarbon material; and
removing the reaction product.

23. The method of claim 22 wherein the chlorocarbon material comprises CCl₄, CHCl₃, CH₂Cl₂, CH₃Cl, COCl₂, or a combination thereof.

24. The method of claim 22 wherein the reactive composition further comprises HfSiₓO_{y} or ZrSiO₄.

25. The method of claim 22 wherein the reactive composition comprises more than one chlorocarbon material.
